(19) United States
(12) Patent Application Publication
(10) Pub. No.: US 2010/0051083 A1
(43) Pub. Date: Mar. 4, 2010

(54) SOLAR TRACKING PLATFORM WITH ROTATING TRUSS

(76) Inventor: Bill BOYK, BANKS, OR (US)

Correspondence Address: MARGER JOHNSON & MCCOLLOM, P.C., 210 SW MORRISON STREET, SUITE 400, PORTLAND, OR, 97204, US

(21) Appl. No.: 12/434,534

(22) Filed: May 1, 2009

Related U.S. Application Data
(60) Provisional application No. 61/094,014, filed on Sep. 3, 2008.

(51) Int. Cl. H01L 31/042; E04B 7/16; E04H 14/00

(52) U.S. Cl. 136/244; 52/636; 52/66; 52/1

(57) ABSTRACT

A platform has a truss frame including at least one frame chord, legs attached to the frame chord, and at least one assembly mounted between the legs and the frame chord, the assembly including an actuator arranged to move the frame chord. A solar tracking platform has a truss frame including at least one frame chord, block assemblies attached to the frame chord, at least one solar panel attached to the block assemblies, legs attached to the frame chord, and at least one assembly attached to the frame chord, the assembly including an actuator to move the frame chord.

### RELATED APPLICATIONS

This application claims priority to and is a continuation of U.S. Provisional Patent Application No. 61/094,014, filed Sep. 3, 2008.

### BACKGROUND

Solar support systems commonly use fixed posts and rail systems that require short spans and several mounting points, and are unable to move in any direction. Such systems do not obtain the maximum amount of sunlight available each day.

Originally, these solar support systems required several penetrations in roof structures and took several days to provide accurate alignment and location of stable mounting structures. However, customers objected since these systems introduced leak points and were supported in the middle of roof spans that were directly over interior living spaces. Also, customers were not able to maximize their solar potential because the systems were in a fixed and stationary orientation to the sun.

Therefore, solar support system manufacturers and contractors encouraged customers to install larger, more costly systems to increase their solar gathering potential. If a customer wanted the maximum solar potential the customer had to increase the number of mounting points resulting in increasing the leak potential and roof loads.

Finally, solar support systems are designed as static structures that are unable to adjust to new solar improvements. They are limited to the original footprint mounting points and structure because customers do not want to disturb the original penetration points. Also, if roof repair is necessary, several, if not all of the sections, mounts and rails must be removed which adds to the total cost of roof repair, reinstallation of the old solar support system without the benefit of a solar tracking platform.

### BRIEF DESCRIPTION OF THE DRAWINGS

FIG. 1 shows an embodiment of a solar panel tracking platform.

FIG. 2 shows an embodiment of an actuator cam arm.

FIG. 3 shows an embodiment of a top tube frame chord

FIG. 4 shows a bottom of an embodiment of a plate with web supports

FIG. 5 shows a front view of an embodiment on an actuator cam arm connecting with an actuator and end frame chord.

FIG. 6 shows a side view of an embodiment of an actuator cam arm connecting with an actuator.

FIG. 7 shows a side view of an alternative embodiment of an actuator.

FIG. 8 shows a side view of an alternative embodiment of an actuator.

FIG. 9 shows an end view of an alternative pivot point assembly.

FIG. 10 shows a side view of a solar power alternative fuel kiosk.

FIG. 11 shows a shipping container adaptable to become an alternative fuel container.

FIG. 12 shows a top view of a roadside alternative fuel station layout.

FIG. 13a-b shows front and top views of an alternative fuel station kiosk at a station.

FIG. 14 shows an end view of an alternative fuel station kiosk at a station.

FIG. 15 shows an end view of an alternative fuel station kiosk for battery exchange.

FIG. 16 shows an end view of an alternative pivot point assembly.

### DETAILED DESCRIPTION

It is possible to provide a solar tracking platform to which solar panels are mounted. The solar tracking platform tracks the trajectory of the sun during the day, maximizing the solar ray collection and the efficiency of the system. The embodiments of the platform allow it to be mounted either in an East-West configuration or a North-South configuration, either on the top of a structure or on the ground.

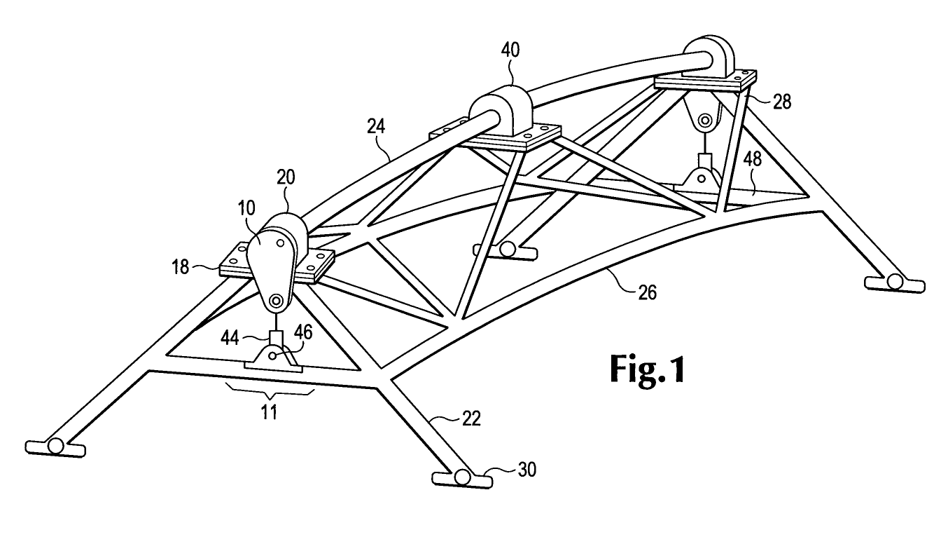

FIG. 1 shows an embodiment of a solar tracking platform. In this embodiment, the solar tracking platform has an A-frame configuration. Moveable feet 30 attached to end support legs 22 can spread at 90 degree angles to accommodate stable mounting points. This allows the platform to exist without tipping over under loads. Frame chords 24, 26, and 48 connect to each support leg. A 90-degree web support 28 supports the frame chords. The legs may consist of hollow aluminum tubes. However, the legs and chords can consist of any material that can support the load weights, such as aluminum, carbon fiber, steel, fiberglass, impregnated or laminated fibrous materials, various plasticized materials, impregnated natural woods, straws, and recycled materials, as examples.

An assembly 11 resides at each end of the A-frame configuration. In the example here, the assembly 11 consists of an actuator cam arm 10, an actuator 44, and a trunnion mount 46. This assembly attaches to an end frame chord such as 48, with a connection that rotates between a trunnion mount and a cam arm driven by an actuator 44. The actuator can be activated by several power sources such as electric, air or hydraulic.

In one embodiment, the power provided to the actuator may come from solar panels mounted on the platform. Excess power could be stored in batteries on or outside the platform, and then the stored power could be used to at least partially power the actuator or auxiliary equipment on or outside the platform.

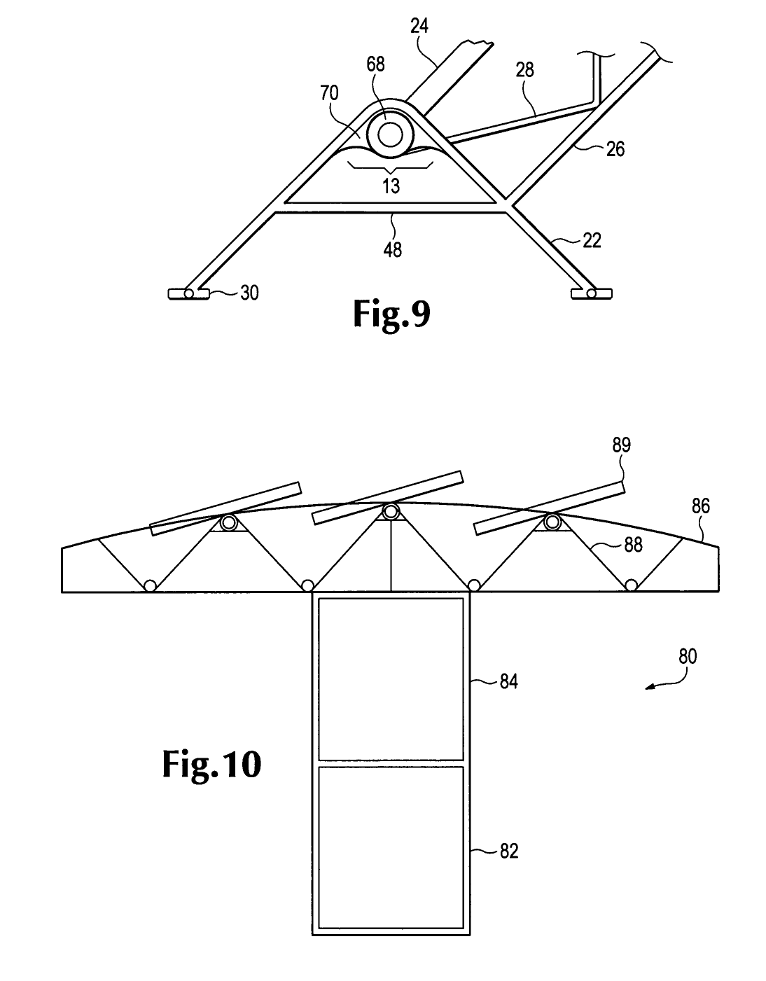

The assembly 11 connects to a pillow block bearing plate 18 at each end of the platform that in turn is mounted atop the apex of web support 28 and end support legs 22. The top tube frame chord 24 passes through each pillow block bearing 20 with a radius bend to compensate for heavy loads or with no bend for lighter loads. The top tube frame chord may also pass through a top pillow block bearing mounted to a plate or a lower center of gravity center truss assembly as will be discussed with regard to FIG. 9.

The basic structure of the platform has moveable feet, such as 30, extensible legs, such as 22, a truss frame such as the one shown here consisting of web supports, legs, and frame chords, and a center rail such as the top tube frame chord and the assemblies that can move to allow solar panels mounted on it to move. Various specific embodiments of components of this structure are discussed in the remaining figures, with the understanding that these are possible embodiments and implementations and are not intended to limit the scope of the claims.

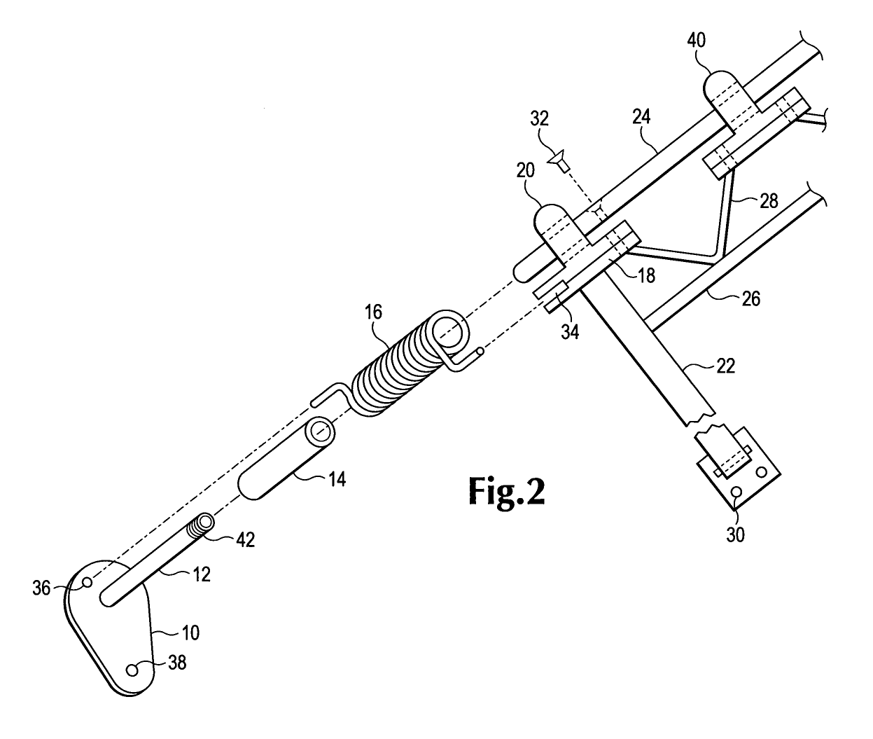

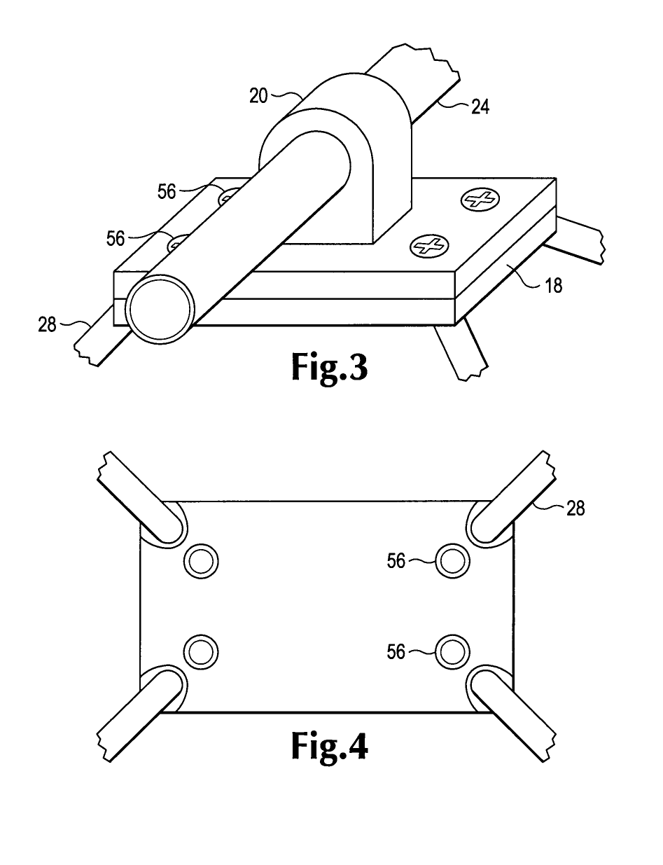

FIG. 2 shows an exploded view or a torsion assembly that is one component that allows the center rail of the system to move. In FIG. 2 actuator cam arm 10 has a least one actuator locator hole 38 and cam locator hole 36 to mount the assembly. The interior extension tube 12 is encompassed with a nylon sleeve 14, extending from the cam arm to position 42, and a torsion spring 16 that slide onto the extended top tube frame chord and the lower leg of the torsion spring 16 passing into plate locator hole 34 on the pillow block bearing plate 18. The plate locator hole 34 faces actuator locator hole 38 and the interior extension tube 12 and may be pre-drilled into the pillow block bearing plate 18 that connects to the pillow block bearing 20 by a screw 56, shown in FIG. 3. The interior extension tube 12 passes into the top tube frame chord 24 and is connected by a screw such as 32.

In FIGS. 3 and 4, web supports such as 28 are attached to the bottom of the pillow block bearing plate 18 by welds and placed at the corners of the plate. Pre-drilled holes in the face of the bearing plate 18 and the bearing 20 are threaded to accept the screw 56 mentioned above to connect the pillow block bearing 20 to the plate 18.

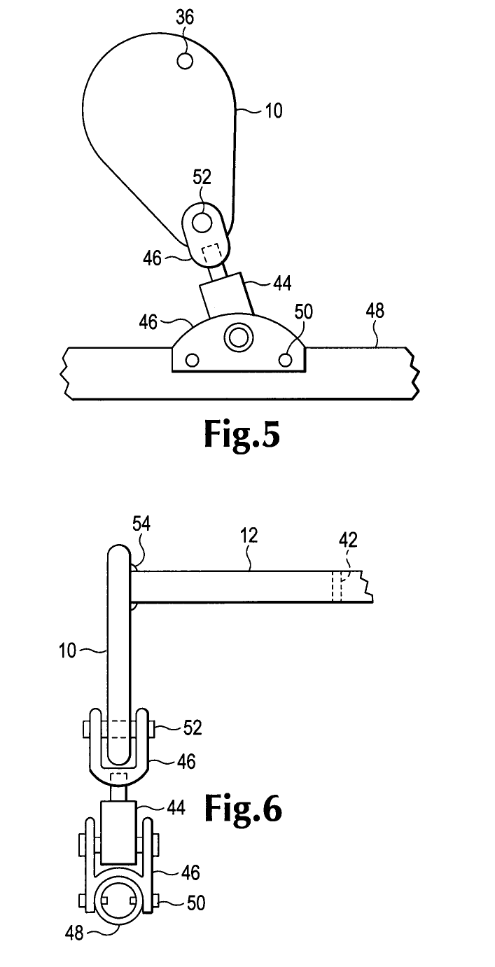

Additional embodiments are shown in FIGS. 5 and 6. In each embodiment, the actuator connects between the trunnion 46 and the actuator cam arm 10 by rotating pivot points located at the farther ends of the actuator. In FIG. 5, the actuator can arm connects to the trunnion mount 46 by a trunnion pin 52. The trunnion mount 46 then mounts to the end frame chord 48 by a screw 50. In FIG. 6, it can be seen that the interior extension tube 12 is welded to the actuator cam arm 10 at welds 54, in turn mounted to the trunnion mount 46 by the trunnion pin 52.

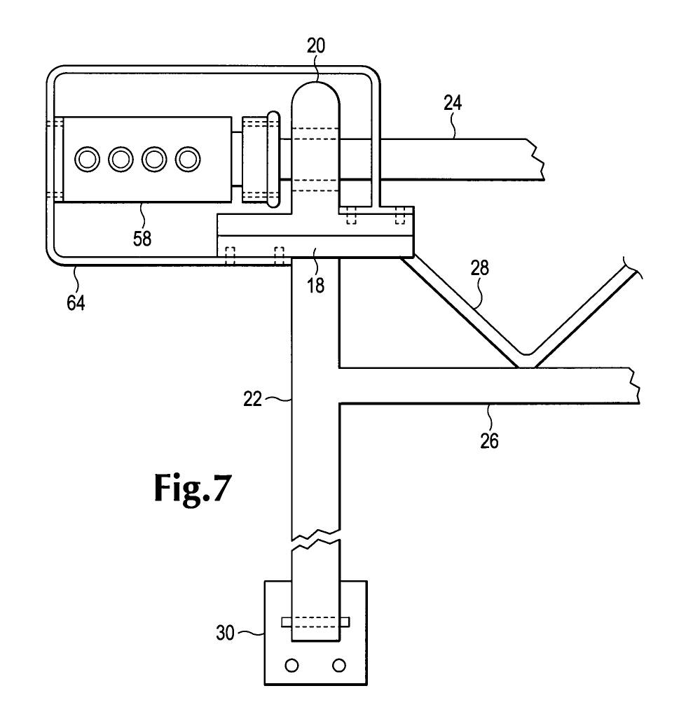

In FIG. 7, an alternative actuator consisting of a rotary joint 58 is shown in side view. The actuator 58 is mounted directly to the top tube frame chord 24 at the end that passes through the pillow block bearing 20. The back end of the actuator is attached to the cover 64 and the top of the cover 64 is attached to the pillow block bearing 20. The bottom of 64 is attached to the bearing plate 18. This configuration enables the rotary joint to be aligned in a straight path with the top tube frame chord 24. For completeness, one can see that the web support 28 also connects to the plate 18, as does the support leg 22.

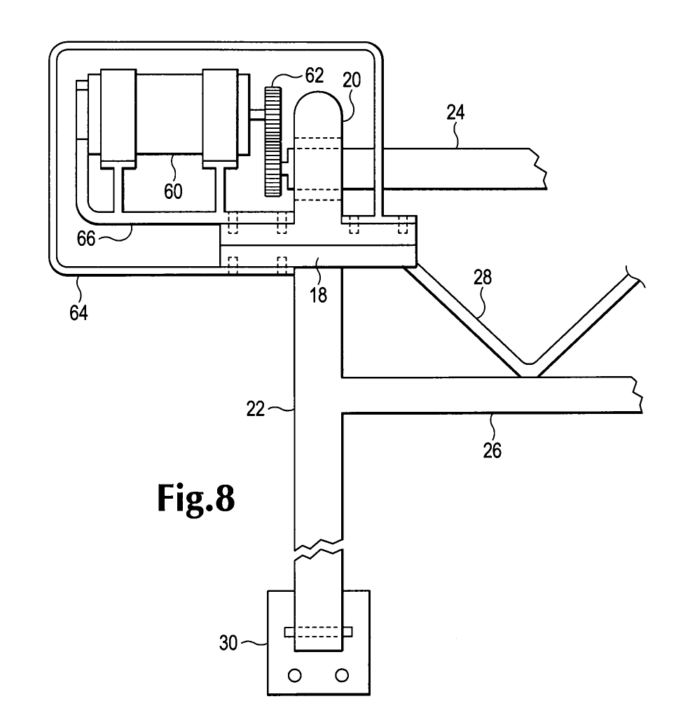

In FIG. 8, an alternative actuator, a geared electromechanical motor having a servo-motor 60 and a gear 62, is shown in side view. The actuator is mounted to a motor base 66 and the front servo-motor gear 62 is attached to a gear located at the end of top tube frame chord 24. The bottom of 66 is attached to 20. The top of 64 is attached to 20 and the bottom of 64 is attached to 18. This configuration enables the gears to engage and rotate the top tube frame chord 24.

As mentioned in the discussion of FIG. 2, one could use an alternative to assembly 11, shown in FIG. 9. In FIG. 9, center end bearing 68 and center truss plate 70 may connect to center shaft 24 and perform the same function as the inline pillow block assembly 40. The top tube frame chord passes through assembly 13. Either the actuator 58 from FIG. 7 or the servo-motor 60 from FIG. 8 may rotate 24 and can be connected to 70 at each end of the truss. The lower pivot point assembly 13 may provide better center of gravity weight distribution of loads and therefore, better stability in bad weather. The top tube frame chord 24 passes through and rotates in an encompassed bearing 68 that attaches to a welded or stamped plate below the round apex of legs 22 and above in-line web supports 28. The bottom of plate 70 is wide to accept welded, glued, stamped or pressed web supports 28 at each in-line connection and at each end of the truss.

In this manner, it is possible to provide a platform, which can span long distances without mid-span penetration points. The platform can track the sun and yield maximum sun gathering capabilities on a daily basis. The platform can adapt to new solar technology and reduces the number of solar panels required to obtain the maximum amount of sunlight produced each day.

The platform may include a controller to control the rate of rotation of the sun by controlling the actuator. The controller could be a simple as a pre-programmed timer, programmed with the sunrise and set times for a particular location. The timer would then control the time the platform begins to rotate, as well as when it stops and returns to its ‘morning’ position. More complex arrangements are also possible, including a light sensor located on the panels to provide illumination data to a microcontroller, the microcontroller to rotate the platform in accordance with the gathered information.

The platform may be pre-assembled eliminating timely installation and can easily mount to the most stable and structurally sound roof members with a minimum of disruption to roof penetrations, and can be easily removed and reinstalled for roof repair. The platform can be easily transported and installed at remote locations, reduces footprint size, hardware costs, and potential roof leaks. The platform may be supplied in pre-assembled and packaged kits, and may be installed in large arrays, reducing man-hour labor costs.

The platform can be mounted on both East-West and North-South facing roof structures, or may be ground mounted on extreme sloped hillsides, rough ground locations and orientated in a complete vertical position.

With the portability and ease of installation, these truss platforms allow solar power to be used in unique and creative ways. As the demand for energy alternatives to oil and gasoline increases, the ability to install roadside fueling stations that are self-powered using solar energy becomes significant. One such application is an alternative fuels delivery station that can provide several alternative fuels for vehicles such biodiesel, ethanol, compressed natural gas, liquid and compressed methane, hydrogen and electric power for electric vehicles.

The increased efficiency resulting from the movable mounting results is sufficient extra electricity to be available beyond the needs of the station itself. This enables the solar tracking system to provide its extra energy to electric vehicles.

The power needs of the station would include any electricity needed to power motors or structures that move the solar panel mountings, any pumps to move or dispense fuels, as well as any illumination provided and to possibly power other accessories such as a point of sale system to authorize credit card transactions.

An example of the base configuration that provides for a solar-powered alternative fuel station is shown in FIG. 10. In keeping with being environmentally friendly, one possible structure upon which the tracking platform could mount is a stack of unused shipping/cargo containers. Currently, a worldwide surplus of these containers exists and not only can one obtain them for a reasonable price, it allows the reuse and reduction of high carbon dioxide manufactured steel products. While the below discussion will include these shipping/cargo containers as the example of a liquid fuel container, no such limitation is intended nor should one be implied.

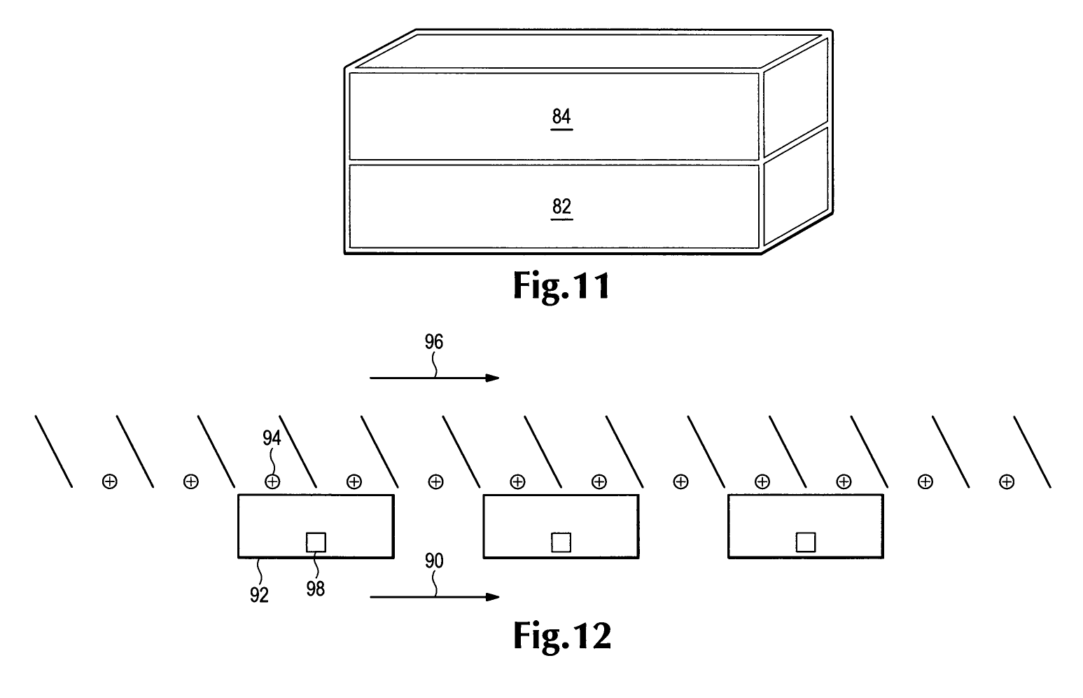

The alternative fuel stand 80 shown in FIG. 10 will become the structure around which an alternative fuel station may be based, as will be discussed later. For purposes of discussion here, the associated dimensions of a typical shipping or cargo container are shown, as well as the relative dimensions of the solar tracking platform support structure 88. In this instance, the stand 80 consists of two shipping/cargo containers 82 and 84, each being 8 feet wide and 8½ feet tall, resulting in an overall stand height of approximately 17 feet. Inside each container are tanks that hold alternative fuels such as biodiesel, ethanol, CNG, liquid or compressed methane, hydrogen and battery arrays for electricity storage. A side perspective view of this stand is shown in FIG. 11; these containers typically have a length of approximately 20 or 40 feet. One or more tanks capable of storing and dispensing the alternative fuels will reside inside the shipping/cargo containers. The typical door and lock configuration may allow a fuel provider easy access to switch out empty tanks for full ones, or pump more fuel into low tanks, depending upon the implementation of the tanks.

In most states, biodiesel is not classified as a dangerous substance and can be ‘self-served’ allowing these alternative fuel stations to be created just about anywhere. As will be discussed in more detail later, a typical highway rest stop with dual lanes for trucks and cars may make an ideal location. The presence of the solar tracking platforms makes these stations self-sufficient. The solar tracking platforms are mounted atop 82 and 84 on canopy structure 86. Solar panels 89, not shown in detail here, are mounted on the solar tracking platform 88 and provide power to the alternative fuels station.

FIG. 12 shows a top view of an alternative fuel station that may be installed anywhere without regard to power. Each solar-powered kiosk 92 consists of an alternative fuels stand, such as 80 from FIG. 10 and a pump/control module 98. Lane 90 would be for alternative liquid or vapor fuel vehicles to pull in next to the stand and fill up their tanks. Lane 96 would have parking slots with power units, such as 94, for people to power up electric vehicles.

The pump/control module 98 may provide several services in addition to pumping the liquid or vapor alternative fuels. It may act as a wireless point of sale to allow customers to perform credit card transactions, control the flow of liquid or vapor alternative fuels between tanks if more than one tank is present at each kiosk, send notifications to service company that one or more tanks are low, etc. It may also meter the electricity power points and charge the customer accordingly depending upon the power taken. The pump/control module 98 may also monitor the solar panel system and ensure that the panels remain functional. The pump/control module may also include a battery bank and may include monitoring of the battery bank to ensure that the station will remain functional during the dark hours or heavy usage.

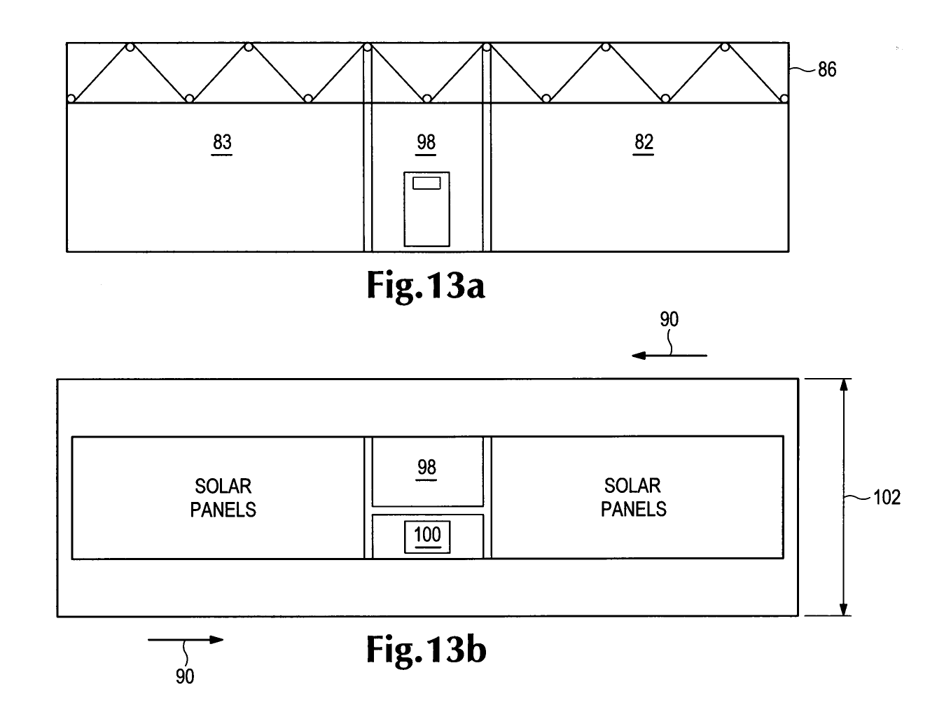

FIGS. 13a and 13b show front and top views of a possible alternative fuels kiosk. The alternative fuels station, such as that shown in FIG. 12, may consist of one or more of these kiosks. In FIG. 13a, the front view of the kiosk shows the pump/control module 98 between two 20 foot single-stacked containers 82 and 83 or one long 40 foot single-stacked container with a center divided compartment that would provide liquid or vapor alternative fuels. The canopy structure 86 would provide the mounting for the solar tracking platforms. In this configuration, the station does not include electric power points.

In FIG. 13b the pump/control room or module 98 includes a pump 100 for pumping the liquid or vapor alternative fuels. The containers 82 and 83 cannot be seen in this view because of the solar panels on the top of the solar tracking platform(s). The entire width of the canopy may extend a width 102 to provide coverage for the customer using the station. Again, as can be seen by the lanes 90, this is a liquid or vapor alternative fuels kiosk only.

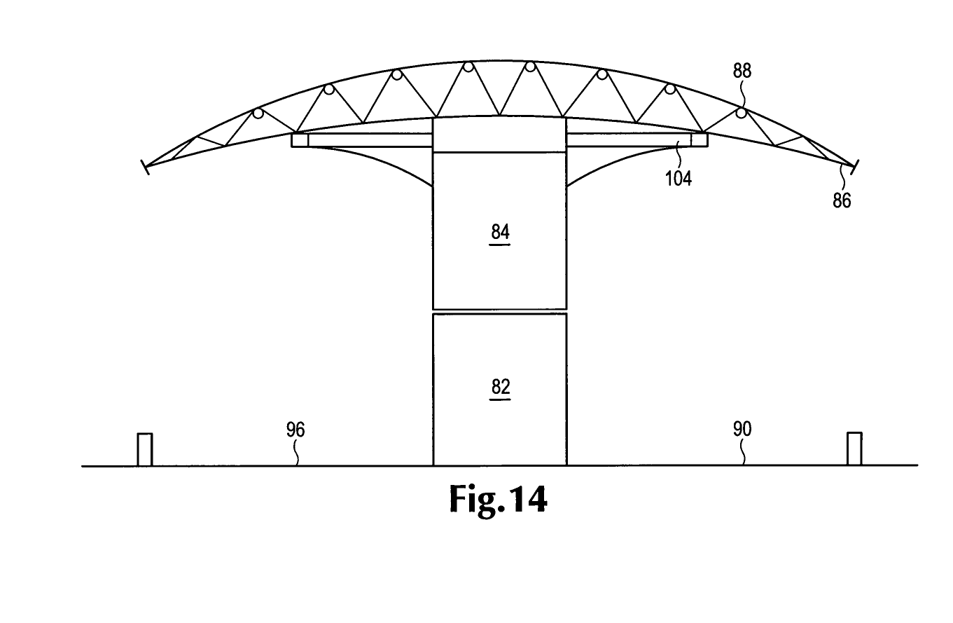

FIG. 14 shows an end view of an alternative fuel/electric kiosk. The kiosk in this embodiment consists of a stack configuration of containers 82 and 84. The canopy structure 86 provides both a support structure for the attachment points for the solar tracking platforms such as 88 from FIG. 10 as well as providing coverage for the customer. Canopy structure 86 is activated by hydraulic arms 104 that elevate the northern end to the seasonal solar altitude. This embodiment has both a liquid or vapor alternative fuel lane 90, and an electric lane such as 96. A curb may act as a boundary of these lanes.

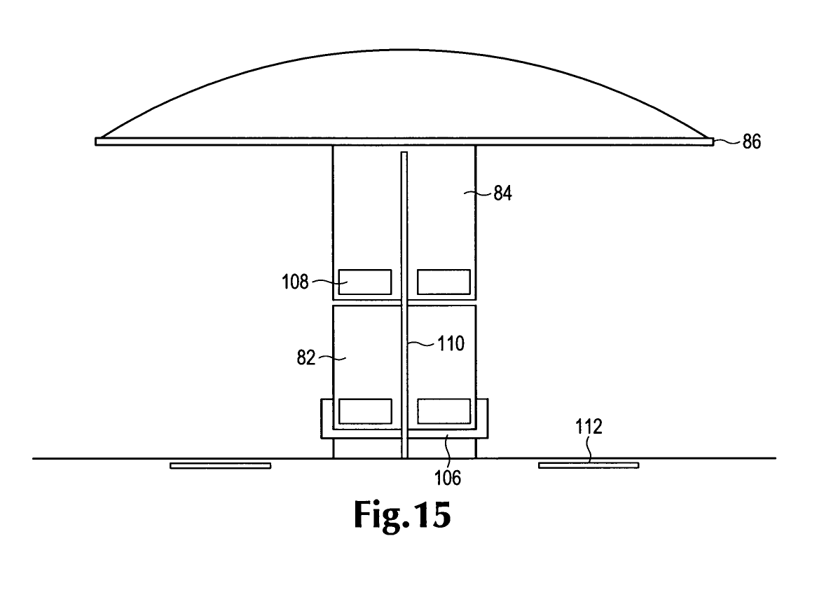

In addition to the ability to dispense alternative fuels and provide recharging services, the kiosk may also allow battery exchange and battery recharging by electric utility grid during non-peak load periods. FIG. 15 shows an end view of an above ground battery exchange platform inside cargo or shipping containers 82 and 84. A hydraulic platform 106 exchanges newly charged batteries 108 with batteries having a low charge in electric vehicles. The arm 106 extends and retracts from 82, allowing the driver or station attendant to place the battery with low charge on the arm and to take a newly charged battery. This system may have completely automated battery retrieval and placement, eliminating the need for an attendant or for the driver to exit the car.

An elevated drive conveyor track, such as one made of flexible steel, positions the battery on the hydraulic platform. An in-ground alignment sensor and vehicle authorizing code pad 112 communicates with the control room or module 98 shown previously and activates the arm 106 and the track 110. Solar panels, such as those shown previously, reside on the solar tracking platform in turn residing on the canopy 86. These panels provide power to the exchange station and the batteries undergoing charging.

As mentioned above, the self-sufficiency of these kiosks makes possible the ability to ‘drop’ them just about anywhere. In many freeway rest stops, for example, there are two lanes, one for trucks and one for cars. One could easily imagine placing one of these kiosks in between the two lanes such that the ‘truck’ lane would become a fueling lane for liquid or vapor alternative vehicles and the ‘car’ lane would become a recharging lane for electric vehicles.

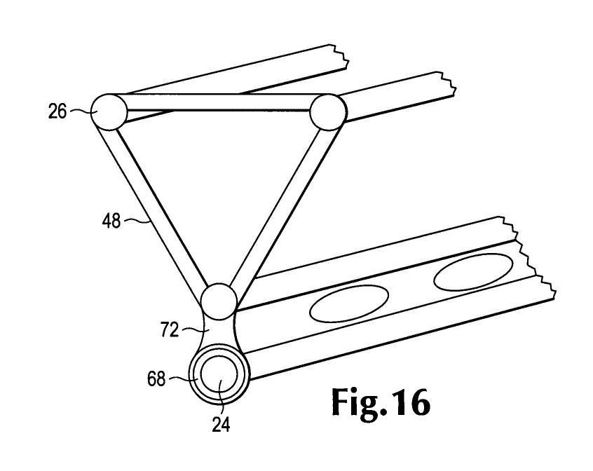

The ability to place them anywhere comes largely from the ability of the platform to track the sun. The unique composition of movable and fixed frame chords allows for this tracking to be oriented either north/south or east/west. Alternative arrangements of the chords are also possible, an example of which is shown in FIG. 16. In FIG. 16, the extension 72 allows for the rotating chord to extend beyond the fixed chord so as to allow this orientation without putting any load on the rotating chord. This is just one example of alternative arrangements that allow the rotation of the platform to occur regardless of the orientation of the support structure.

In this manner, a solar-powered, highly efficient, alternative fuels kiosk or station may come into existence. This not only furthers the goals of environmentally sound powering technologies, but furthers the goals of liquid or vapor alternative and electric vehicle usage. These vehicles have some difficulties in that they are not currently easily fueled without finding a specialized station, or having to get off the freeway and locate a charging station or electrical outlet that is available for use.

While particular embodiments have been described, alternatives, modifications, variations, improvements, and substantial equivalents that are or may be presently unforeseen may arise to applicants and others skilled in the art.

What is claimed is:

1. A platform, comprising:
a truss frame including at least one frame chord;
legs attached to the frame chord; and
at least one assembly mounted between the legs and the frame chord, the assembly including an actuator arranged to move the frame chord.

2. The platform of claim 1, the truss further comprising three frame chords, one top movable frame chord and two side frame chords arranged in parallel to the top frame chord and on opposite side of the top frame chord.

3. The platform of claim 1, the truss further comprising three frame chords, two of the frame chords arranged as a vertical mount standing upright parallel with the other chord, the other chord being a movable frame chord.

4. The platform of claim 1, wherein the assembly comprises an actuator cam arm, an actuator, and a mount to mount the actuator to the frame chord.

5. The platform of claim 1, wherein the assembly comprises a center end bearing and center truss plate connected to the frame chord.

6. The platform of claim 1, wherein the assembly comprises a rotary joint.

7. The platform of claim 1, wherein the assembly comprises a geared electromechanical motor.

8. The platform of claim 1, the platform further comprising feet attached to the legs.

9. The platform of claim 8, wherein the feet comprise movable feet capable of being spread 90 degrees.

10. The platform of claim 1, wherein the legs comprise extensible legs.

11. The platform of claim 1, wherein the chord consists of one of hollow aluminum tubes, carbon fiber, steel, fiberglass, impregnated materials, laminated fibrous materials, plasticized materials, impregnated wood, straw, and recycled materials.

12. The platform of claim 1, further comprising block assemblies arranged to allow attachment of at least one panel to the platform.

13. The platform of claim 1, the feet being located only at ends of the frame chord.

14. The platform of claim 1, the actuator being powered by one of electric power, air pressure or hydraulic power.

15. A solar tracking platform, comprising:
a truss frame including at least one frame chord;
block assemblies attached to the frame chord;
at least one solar panel attached to the block assemblies;
legs attached to the frame chord; and
at least one assembly attached to the frame chord, the assembly including an actuator to move the frame chord.

16. The solar tracking platform of claim 15, further comprising a controller to control the actuator

17. The solar tracking platform of claim 16, wherein the controller comprises a pre-programmed timer.

18. The solar tracking platform of claim 16, wherein the controller further comprises a microcontroller and a light sensor, the light sensor arranged to provide the microcontroller with illumination data, the microcontroller arranged to adjust a rate of rotation of the panel in response to the illumination data.

19. The solar tracking platform of claim 16, wherein the actuator comprises a powered actuator powered by one of electric power, air pressure or hydraulic pressure.

20. The solar tracking platform of claim 15, the platform further comprising batteries arranged to store any surplus power.

21. The solar tracking platform of claim 20, wherein the power stored in the batteries is used to assist in actuating the platform.
